(19) United States
(12) Patent Application Publication
(10) Pub. No.: US 2011/0140722 A1
(43) Pub. Date: Jun. 16, 2011

(54) OBJECT-SENSING DEVICE

(75) Inventors: Wei-Chih Hsu, Taipei (TW); Jhe-Jhao Chang, Taipei (TW); Chi-Wei Kuo, Taipei (TW); Tung-Jung Sung, Taipei (TW); Wen-Jong Wu, Taipei (TW); Yao-Joe Yang, Taipei (TW)

(73) Assignee: NATIONAL TAIWAN UNIVERSITY, Taipei (TW)

(21) Appl. No.: 12/815,078

(22) Filed: Jun. 14, 2010

(30) Foreign Application Priority Data
Dec. 14, 2009 (TW) 98142675

(51) Int. Cl. G01R 27/08

(52) U.S. Cl. 324/693

(57) ABSTRACT

Proposed is an object-sensing device including: a carrier base; at least one first conductive element disposed on a carrying surface of the carrier base; a cover capable of resting seamlessly on the carrying surface and provided therein with a receiving space; a resilient element received in the receiving space; at least one second conductive element disposed on a surface of the resilient element, wherein the surface of the resilient element faces the carrying surface, the at least one second conductive element corresponding in position to the at least one first conductive element; and a sensor electrically connected to the first conductive element and an end of the at least one second conductive element and configured to detect electrical contact between each of the first conductive elements and another end of the at least one second conductive element. The sensor generates a first signal upon affirmative determination and generates a second signal upon negative determination to thereby precisely determine whether an object is present on the carrying surface.

### BACKGROUND OF THE INVENTION

1. Field of the Invention

The present invention relates to object-sensing devices, and more particularly, to an object-sensing device for precisely sensing whether an object is present.

2. Description of the Prior Art

Various proximity sensing devices exist, such as pressure sensing devices for use in sensing pressure and refractive index sensing devices for use in sensing refractive indices.

For example, patients often forget to take medication as scheduled and thereby aggravate their diseases. People living alone, especially the elderly or mostly bed-bound, often fail to take medication as prescribed, adversely affecting their health. Hence, the prior art has disclosed a tablet-sensing device based on pressure-sensing technology and/or refractive index-sensing technology configured to determine whether a drug is present in a drug container to thereby determine whether a patient has taken medication as scheduled, by sensing either the refractive index or the weight of a container.

However, the tablet-sensing device based on the pressure-sensing technology and/or refractive index-sensing technology does have its own disadvantages, namely excessive power consumption and high cost, and therefore is not in widespread use. Furthermore, the physical properties of pressure and refractive index vary from object to object being detected; hence, the tablet-sensing device based on pressure-sensing technology and/or refractive index-sensing technology seldom manifests optimal preciseness. For example, as time passes or upon jostling, a tablet may undergo weight loss or a color change; hence, a change in the refractive index or the weight of a tablet predisposes the tablet sensing device based on pressure-sensing technology and/or refractive index-sensing technology to exhibit errors. Last but not least, the tablet-sensing device based on the pressure-sensing technology and/or refractive index-sensing technology is of little practicality for two reasons. First, there are a wide variety of tablets on the market, but the tablet-sensing device based on the pressure-sensing technology and/or refractive index-sensing technology is tablet-specific and thus is aimed at one and only one type of tablet. Second, pressure-sensing technology and/or refractive index-sensing technology do have limits, such as restraints related to the usage environment (for example, when used in a relatively spacious environment).

Accordingly, it is imperative to provide an object-sensing device that is reliable and practical but consumes less power and is less expensive than conventional object-sensing devices.

### SUMMARY OF THE INVENTION

To overcome the above drawbacks of the prior art and achieve the above and other objectives, the present invention provides an object-sensing device that is reliable and practical but consumes less power and is less costly than conventional object-sensing devices. The object-sensing device comprises: a carrier base having a carrying surface for carrying an object, the carrying surface being provided thereon with at least a first conductive element; a cover capable of resting seamlessly on the carrying surface of the carrier base and provided therein with a receiving space open to the carrying surface; a resilient element received in the receiving space of the cover; at least a second conductive element disposed on a surface of the resilient element, wherein the surface of the resilient element faces the carrying surface, the at least a second conductive element corresponding in position to the first conductive element; and a sensor electrically connected to the first conductive element and an end of the at least a second conductive element and configured to detect electrical contact between each of the first conductive elements and another end of the at least a second conductive element to thereby determine whether an object is present on the carrying surface. The sensor generates a first signal upon determination that each of the first conductive elements is in electrical contact with another end of the at least a second conductive element and generates a second signal upon determination that at least one of the first conductive elements is not in electrical contact with another end of the at least a second conductive element.

In an embodiment, the carrying surface and the resilient element are in seamless contact with each other through an arciform or curviform contact surface therebetween.

The present invention further provides an object-sensing device, comprising: a carrier base having a carrying surface for carrying an object, the carrying surface being provided thereon with at least a first conductive element; a cover capable of resting seamlessly on the carrying surface of the carrier base and provided therein with a receiving space open to the carrying surface; a resilient element received in the receiving space of the cover; a baffle disposed on the resilient element; at least a second conductive element disposed on a surface of the baffle, wherein the surface of the baffle faces the carrying surface, the at least a second conductive element corresponding in position to the first conductive element; and a sensor electrically connected to the first conductive element and an end of the at least a second conductive element and configured to detect electrical contact between each of the first conductive elements and another end of the at least a second conductive element to thereby determine whether an object is present on the carrying surface. The sensor generates a first signal upon determination that each of the first conductive elements is in electrical contact with another end of the at least a second conductive element, and generates a second signal upon determination that at least one of the first conductive elements is not in electrical contact with another end of the at least a second conductive element.

In an embodiment, the carrying surface and the baffle are in seamless contact with each other, as are the baffle and the resilient element. Preferably, the carrying surface and the baffle are in seamless contact with each other through an arciform or curviform contact surface therebetween, as are the baffle and the resilient element.

The present invention further provides an object-sensing device, comprising: a carrier base having a carrying surface for carrying an object, the carrying surface being provided thereon with at least a first conductive element; a cover capable of resting seamlessly on the carrying surface of the carrier base and provided therein with a receiving space open to the carrying surface; a resilient element received in the receiving space of the cover; at least a second conductive element disposed on a surface of the resilient element, wherein the surface of the resilient element faces the at least a first conductive element, the at least a second conductive element being provided with conductive bumps corresponding in position to the at least a the first conductive element; a baffle disposed on the at least a second conductive element and provided with openings corresponding in position to the conductive bumps, respectively; and a sensor electrically connected to the first conductive element and an end of the at least a second conductive element and configured to detect electrical contact between each of the first conductive elements and another end of the at least a second conductive element to thereby determine whether an object is present on the carrying surface. The sensor generates a first signal upon determination that each of the first conductive elements is in electrical contact with another end of the at least a second conductive element and generates a second signal upon determination that at least one of the first conductive elements is not in electrical contact with another end of the at least a second conductive element.

In an embodiment, the carrying surface and the baffle are in seamless contact with each other, as are the baffle and the resilient element. Preferably, the carrying surface and the baffle are in seamless contact with each other through an arciform or curviform contact surface therebetween.

Unlike the prior art, the present invention provides an object-sensing device that comprises a cover, a carrier base, a resilient element, a first conductive element, at least a second conductive element, and/or a baffle in such an integrated manner that the presence of an object is precisely sensed solely by means of the volumetric characteristics of the object. Hence, the object-sensing device of the present invention is conducive to reduction of power consumption and manufacturing costs, applicable to various objects and usage environments, and practical.

### BRIEF DESCRIPTION OF THE DRAWINGS

FIG. 1A is an exploded perspective view of the first embodiment of an object-sensing device according to the present invention;

FIG. 1B is a side cross-sectional view depicting operation of the first embodiment of the object-sensing device according to the present invention;

FIG. 1C is a side cross-sectional view depicting operation of the first embodiment of the object-sensing device according to the present invention;

FIG. 2 is an exploded perspective view of the second embodiment of the object-sensing device according to the present invention; and

FIG. 3 is an exploded perspective view of the third embodiment of the object-sensing device according to the present invention.

### DETAILED DESCRIPTION OF THE EMBODIMENTS

The present invention is herein illustrated with specific embodiments, so that one skilled in the pertinent art can easily understand other advantages and effects of the present invention from the disclosure of the invention. Implementation or application of the present invention can also be achieved by other specific embodiments.

### First Embodiment

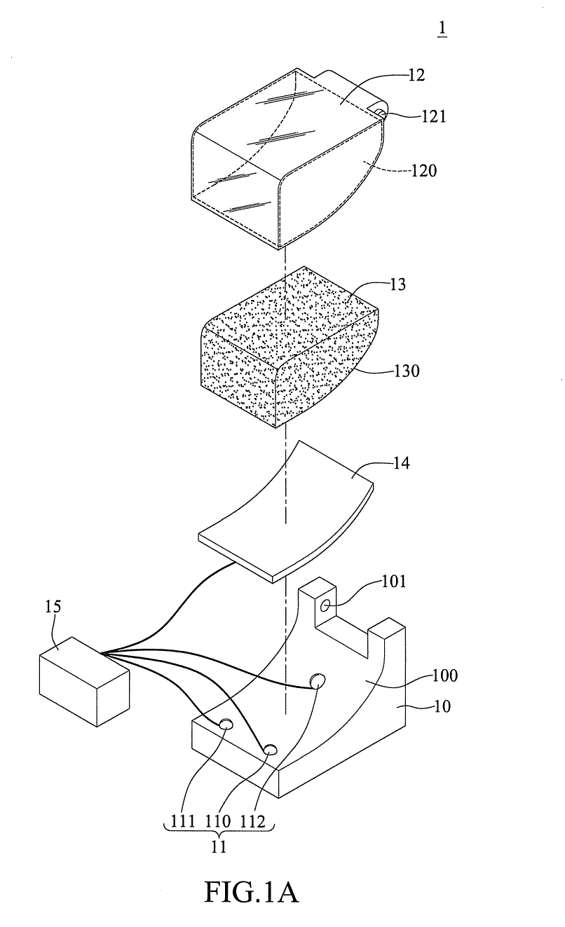

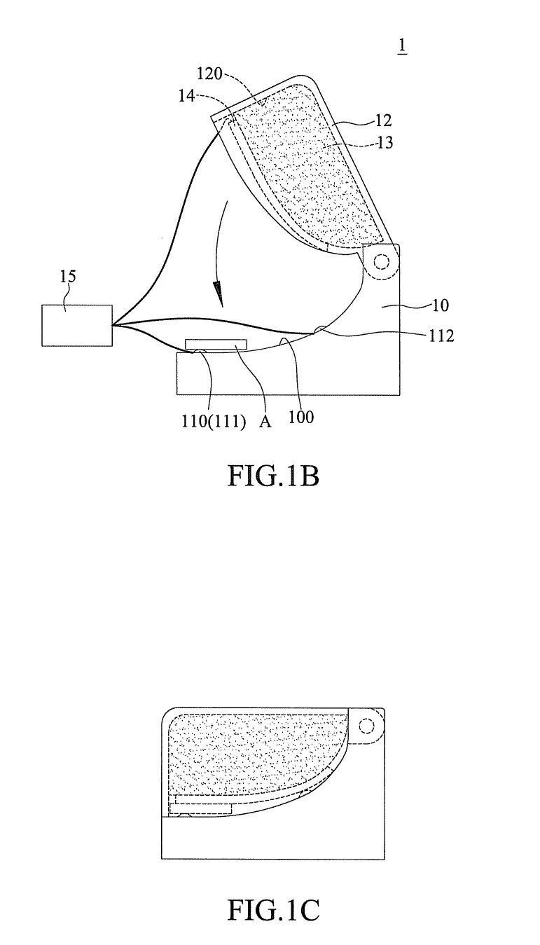

FIG. 1A shows an exploded perspective view of the first embodiment of an object-sensing device according to the present invention. As shown in the drawing, an object-sensing device 1 comprises a carrier base 10, a first conductive element assembly 11, a cover 12, a resilient element 13, at least a second conductive element 14, and a sensor 15.

The carrier base 10 has a carrying surface 100 for carrying an object, such as a tablet or a chip. The carrying surface 100 is provided thereon with the first conductive element assembly 11. The carrying surface 100 is of a planar shape, arciform shape, or curved shape. In the first embodiment, the carrying surface 100 is of an arciform shape for illustrative purposes and has two principal ends, namely a high end and a low end. The high end is higher than the low end such that the carrying surface 100 slopes gently downward from the high end to the low end. Objects put at the high end of the carrying surface 100 readily move downward across the carrying surface 100 under gravity when released. Hence, objects always gather at the low end of the carrying surface 100 to thereby facilitate enhancement of preciseness of the object-sensing device 1.

The first conductive element assembly 11 is provided on the carrying surface 100 of the carrier base 10. In the first embodiment, the first conductive element assembly 11 comprises three first conductive elements 110, 111 and 112. The first conductive elements 110, 111 and 112 are electrically conductive plates or cylinders. However, the shape and structure of the first conductive elements 110, 111 and 112 are not limited to plates or cylinders, and the positions and quantity of the first conductive elements 110, 111 and 112 are variable depending on the design requirements. For example, a single first conductive element 110 could be centrally provided on the carrying surface 100 of the carrier base 10. In other embodiments of the present invention, the first conductive elements 110, 111 and 112 could be leaf springs with bendable legs. The first embodiment is exemplified by a conductive element assembly comprising a plurality of said first conductive elements. In other embodiments, the plurality of said first conductive elements could be replaced by a single conductive element.

Referring to FIG. 1A, the first conductive elements 110 and 111 are positioned at the low end of the carrying surface 100, because, in practice, tablets put on the carrying surface 100 readily move toward the low end thereof under gravity when released. With tablets being more likely to end up at the low end than anywhere else on the carrying surface 100, optimal preciseness in detection of objects on the carrying surface 100 is better provided by having more said first conductive elements positioned at the low end than anywhere else on the carrying surface 100.

The height of the first conductive elements 110, 111 and 112 above the carrying surface 100 is preferably less than the thickness of an object to be detected, so as to ensure that detection of the object to be detected will be precise. For example, where a tablet to be detected is 5 mm thick, the height of the first conductive elements 110, 111 and 112 from the carrying surface 100 is preferably around 3 mm.

The cover 12 can rest seamlessly on the carrying surface 100 of the carrier base 10 and contains a receiving space 120 open to the carrying surface 100. In the first embodiment, the cover 12 and the carrying surface 100 of the carrier base 10 correspond well in shape and profile. The cover 12 is provided with axles 121. The carrier base 10 is provided with axial holes 101 corresponding in position to the axles 121 of the cover 12, respectively. Engagement of the axles 121 and the axial holes 101 allows the cover 12 to be axially coupled to the carrier base 10 to provide for pivoting of the cover 12 for opening and closing the object sensing device 1. In other embodiments of the present invention, the carrier base 10 is provided with the axles 121 and the cover 12 with the axial holes 101. In yet other embodiments, the cover 12 and the carrier base 10 are not axially coupled to each other and thus are not provided with the axles 121 and the axial holes 101, respectively.

The resilient element 13 is received in the receiving space 120 of the cover 12. In the first embodiment, the resilient element 13 is made of synthetic rubber, foam rubber, and/or spongy material and is received in the receiving space 120. In other embodiments of the present invention, the resilient element 13 is a spring. The resilient element 13 is compressible to create sufficient room to accommodate contained objects to be detected and to provide buffering so as to prevent contained objects from being damaged if the cover 12 is quickly brought into contact with the carrying surface 100 of the carrier base 10.

The resilient element 13 has a receiving surface 130 facing the carrying surface 100 and the first conductive element assembly 11. The at least a second conductive element 14 is disposed on the receiving surface 130 of the resilient element 13. In the first embodiment, the at least a second conductive element 14 is an electrically conductive metallic plate or panel and manifests considerable structural strength for preventing the at least a second conductive element 14 from deformation which might otherwise cause misinterpretation of the contained objects. Preferably, the at least a second conductive element 14 conforms to the shape of and abuts against the receiving surface 130 facing the carrying surface 100 and the first conductive element assembly 11. In the first embodiment, the at least a second conductive element 14 is a metallic plate or panel. Electrical contact between the at least a second conductive element 14 and the first conductive elements 110, 111 and 112 will persist provided that the carrying surface 100 neither carries any object nor disengages from the cover 12.

In another embodiment of the present invention, the at least a second conductive element 14 is present in number equal to the number of first conductive elements 110, 111 and 112. For example, unlike in the first embodiment in which a single metallic plate or panel is disclosed, another embodiment of the present invention allows the at least a second conductive element 14 to correspond to the first conductive elements 110, 111 and 112 in number and position, as the at least a second conductive element 14 comprises three separate conductive thin plates of the same electrical potential such that the three separate conductive thin plates lie on the receiving surface 130 facing the carrying surface 100 and the first conductive element assembly 11. Likewise, in yet another embodiment, three said second conductive elements 14 will be in electrical contact with the first conductive elements 110, 111 and 112 of the first conductive element assembly 11, respectively, provided that the carrying surface 100 neither carries any object nor disengages from the cover 12.

The sensor 15 is electrically connected to the first conductive elements 110, 111 and 112 of the first conductive element assembly 11 and an end of the at least a second conductive element 14 so as to determine whether the first conductive elements 110, 111 and 112 are electrically connected to the other end of the at least a second conductive element 14, wherein the other end of the at least a second conductive element 14 is not in contact with the sensor 15. If it is determined that at least one of the first conductive elements 110, 111 and 112 is not electrically connected to the other end of the at least a second conductive element 14, two conclusions can be drawn as follows: the first conductive elements 110, 111 and 112 are not of the same electrical potential concurrently; and an object is present on the carrying surface 100. Conversely, If it is determined that all of the first conductive elements 110, 111 and 112 are electrically connected to the other end of the at least a second conductive element 14, two conclusions can be drawn as follows: all of the first conductive elements 110, 111 and 112 are of the same electrical potential concurrently; and no objects are present on the carrying surface 100.

Preferably, if the sensor 15 determines that the other end of each of the first conductive elements 110, 111 and 112 is electrically connected to the other end of the at least a second conductive element 14, a first signal can be selectively sent out to indicate that no object is present on the carrying surface 100 of the carrier base 10. Conversely, if the sensor 15 determines that the other end of at least one of the first conductive elements 110, 111 and 112 is not electrically connected to the other end of the at least a second conductive element 14, a second signal can be selectively sent out to indicate that an object is present on the carrying surface 100 of the carrier base 10. In the first embodiment, the sensor 15 is, but is not limited to, a microcomputer, a computer, or a server. The first signal and the second signal are, but are not limited to, sound, images, and/or vibration.

In other embodiments of the present invention, the sensor 15 selectively sends the result of detection to an external device (not shown) by a wireless communication technique, such as Bluetooth, infrared, or high-frequency signals. The external device, which is exemplified by a mobile phone, notebook computer, a personal computer and/or home security system, sends the signals to a remote monitoring system through a wired and/or wireless communication network, to thereby be applicable to long-distance or medical care involving remote-monitoring.

The carrying surface 100 and the resilient element 13 are in seamless contact with each other. Preferably the carrying surface 100 and the resilient element 13 are in seamless contact with each other through an arciform or curviform contact surface therebetween.

FIG. 1B and FIG. 1C show cross-sectional side views of the operation of the first embodiment of the object-sensing device 1 according to the present invention.

Referring to FIG. 1B, the first conductive element assembly 11 (as in FIG. 1A) comprising the first conductive elements 110, 111 and 112 is provided on the carrying surface 100 of the carrier base 10 of the object-sensing device 1. The cover 12 of the object-sensing device 1 is axially coupled to the carrier base 10. The receiving space 120 of the cover 12 receives the resilient element 13. The at least a second conductive element 14 is sheet-shaped and provided on a surface of the resilient element 13 such that the at least a second conductive element 14 is sandwiched between the resilient element 13 and the carrying surface 100. The sensor 15 of the object-sensing device 1 is electrically connected to the first conductive elements 110, 111 and 112 and one end of the at least a second conductive element 14. Referring to FIG. 1C, in the first embodiment, an object to be detected A is placed on the carrying surface 100 in the manner that the object A covers the first conductive element 110. Once the cover 12 is shut and rests on the carrier base 10, the at least a second conductive element 14 will be electrically connected to the first conductive element 112 only; hence, the sensor 15 will detect electrical disconnection of the first conductive elements 110, 111 and therefore generate the second signal for indicating the presence of the object A on the carrying surface 100 of the carrier base 10.

Some of the stress generated by the shutting of the cover 12 is absorbed by the resilient element 13 of the object-sensing device 1 of the present invention and therefore does not cause any structural damage to the object being detected A. Hence, the object-sensing device 1 of the present invention is applicable to a fragile object, such as a tablet or a chip. Even if the object being detected A is positioned between the first conductive elements 110, 111 and 112 and thereby does not cover the first conductive elements 110, 111 and 112, misinterpretation is unlikely to occur, because the height from top ends of the first conductive elements 110, 111 and 112 to the carrying surface 100 varies with the thickness of the object being detected A.

### Second Embodiment

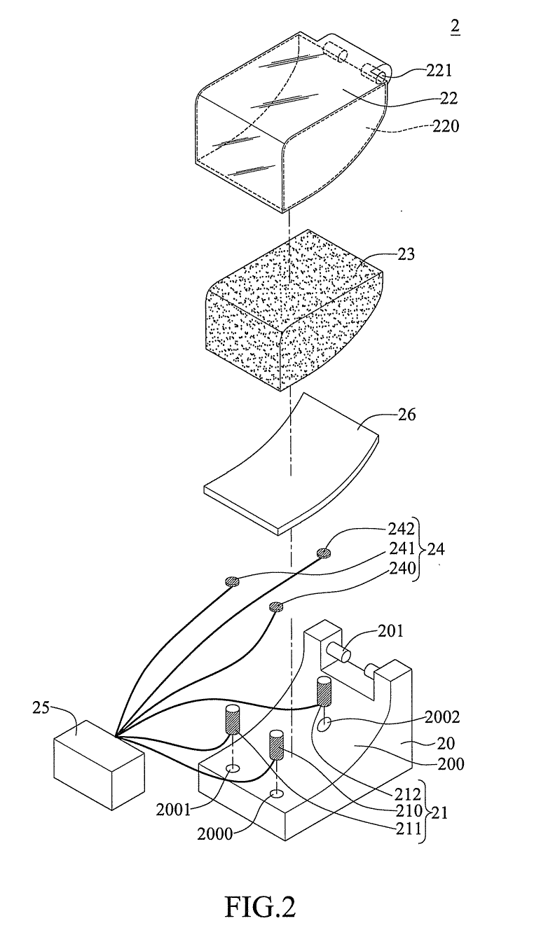

FIG. 2 shows an exploded perspective view of the second embodiment of the object-sensing device according to the present invention. As shown in the drawing, an object-sensing device 2 comprises a carrier base 20, at least a first conductive element 21, a cover 22, a resilient element 23, at least a second conductive element 24, a sensor 25, and a baffle 26.

The carrier base 20 has a carrying surface 200 for carrying an object. The carrying surface 200 is provided thereon with at least a first conductive element 21. In the second embodiment, the at least a first conductive element 21 comprises three conductive posts 210, 211 and 212. The conductive posts 210, 211 and 212 correspond in position to post holes 2000, 2001 and 2002 disposed on the carrying surface 200. The length of the conductive posts 210, 211 and 212 exceeds the depth of the post holes 2000, 2001 and 2002 so as for the conductive posts 210, 211 and 212 to be exposed from the carrying surface 200. In other embodiments of the present invention, the post holes 2000, 2001 and 2002 are selectively provided therein with a resilient element (not shown) whereby the conductive posts 210, 211 and 212 are capable of producing a resilience force.

The cover 22 can rest seamlessly on the carrying surface 200 of the carrier base 20 and contains a receiving space 220 open to the carrying surface 200. In the first embodiment, the cover 22 is provided with axial holes 221. The carrier base 20 is provided with axles 201 corresponding in position to the axial holes 221, respectively. Engagement of the axial holes 221 and the axles 201 allows the cover 22 to be axially coupled to the carrier base 20.

The resilient element 23 is received in the receiving space 220 of the cover 22 and is a spring or is made of synthetic rubber, foam rubber, and/or spongy material. The baffle 26 is disposed on a surface of the resilient element 23, wherein the surface of the resilient element 23 faces the carrying surface 200. In the first embodiment, the baffle 26 is an insulating plate made of plastic and is of considerable structural strength.

The at least a second conductive element 24 is disposed on a surface of the baffle 26, wherein the surface of the baffle 26 faces the carrying surface 200. The at least a second conductive element 24 corresponds in position to the at least a first conductive element 21. In the second embodiment, the at least a second conductive element 24 comprises conductive pieces 240, 241 and 242. The conductive pieces 240, 241 and 242 correspond in position to the conductive posts 210, 211 and 212, respectively. In other embodiments of the present invention, the conductive pieces 240, 241 and 242 are of a columnar shape and are single metallic plates or panels as disclosed in the first embodiment.

The sensor 25 is electrically connected to the conductive posts 210, 211 and 212 of the at least a first conductive element 21 and one end of the conductive pieces 240, 241 and 242 of the at least a second conductive element 24 so as for the conductive pieces 240, 241 and 242 to be at the same electrical potential. The sensor 25 determines whether each of the conductive posts 210, 211 and 212 is electrically connected to the other end of a corresponding one of the conductive pieces 240, 241 and 242. A first signal is sent out in response to an affirmative determination. The second signal is sent out in response to a negative determination. In the second embodiment, the first signal indicates absence of any object on the carrying surface 200, and the second signal indicates presence of an object on the carrying surface 200.

The carrying surface 200 and the baffle 26 are in seamless contact with each other, as are the baffle 26 and the resilient element 23. Preferably, the carrying surface 200 and the baffle 26 are in seamless contact with each other through an arciform or curviform contact surface therebetween, as are the baffle 26 and the resilient element 23. In the second embodiment, the resilient element 23 is not only compressible to create room for receiving the object to be detected but is capable of producing a resilience force under which the baffle 26 resiliently rebounds. Hence, upon completion of a sensing operation, the baffle 26 automatically returns to its original position. Furthermore, the resilient element 23 functions as a buffer for preventing the object being detected from being damaged when the cover 12 is rapidly or forcefully closed on the carrying surface 100 of the carrier base 10.

### Third Embodiment

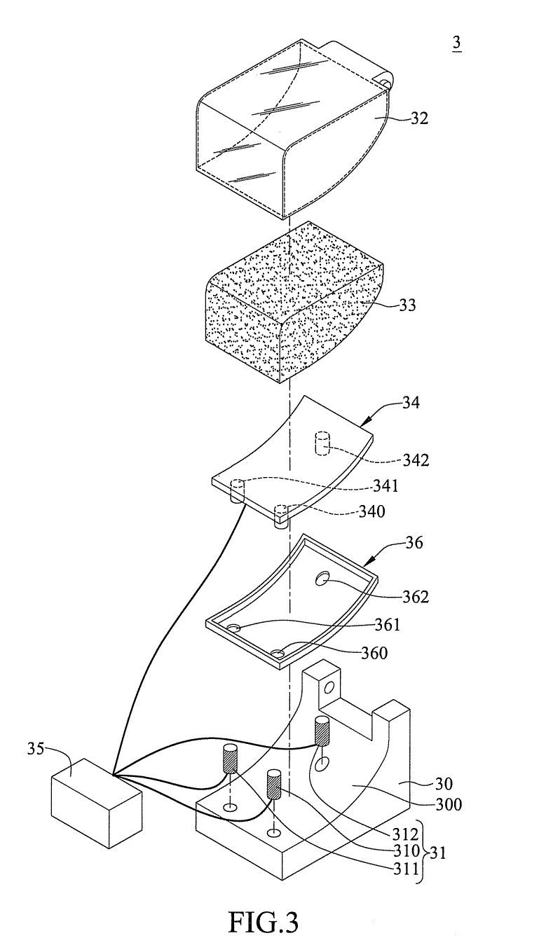

Referring to FIG. 3 shows an exploded perspective view of the third embodiment of the object-sensing device according to the present invention. As shown in the drawing, an object-sensing device 3 comprises a carrier base 30 with a carrying surface 300, conductive posts 310, 311, 312 of a first conductive element 31, a cover 32, a resilient element 33, conductive bumps 340, 341, 342 of at least a second conductive element 34, a sensor 35, and a baffle 36.

The third embodiment differs from the first and second embodiments in that, in the third embodiment, the at least a second conductive element 34 and the baffle 36 match and together form an assembly structure to thereby allow the at least a second conductive element 34 to be provided with conductive bumps 340, 341, 342 corresponding in position to the conductive posts 310, 311, 312 and allow the baffle 36 to be provided with openings 360, 361, 362 corresponding in position to the conductive bumps 340, 341, 342. Preferably, after the at least a second conductive element 34 and the baffle 36 are put together, conductive bumps 340, 341, 342 penetrate and are exposed from the openings 360, 361, 362, respectively. In practice, given equalization of the electrical potential of the conductive bumps 340, 341, 342, which is the purpose of the sensor 35, it is feasible to determine whether an object is present on the carrying surface 300 by detecting electrical contact between or a change in electric potential between the conductive bumps 340, 341, 342 of the at least a second conductive element 34 and the conductive posts 310, 311, 312 of the first conductive element 31, respectively.

The baffle 36 is of considerable structural strength and thus does not deform during a subsequent sensing operation. The carrying surface 300 and the baffle 36 are in seamless contact with each other, as are the baffle 36 and the resilient element 33. Preferably, the carrying surface 300 and the baffle 36 are in seamless contact with each other through an arciform or curviform contact surface therebetween, as are the baffle 36 and the resilient element 33.

In conclusion, an object-sensing device of the present invention comprises a carrier base with a carrying surface, a first conductive element, a cover, a resilient element, at least a second conductive element, a sensor, and/or a baffle. Hence, the object-sensing device of the present invention precisely senses whether an object is present on the carrying surface, using the volumetric characteristics of the object to be detected and electrical contact between the first conductive element and the at least a second conductive element. Compared with the prior art, the present invention has less power consumption and involves less manufacturing costs and enhances preciseness of detection. Various signals can be generated by the sensor of the object-sensing device of the present invention to be utilized by an electronic device, a computer device, a telecommunication device, and/or network communication device, and the various signals thus generated are applicable to various usage environments, such as drug detection, chip detection, or long-distance medical detection, so as to be practical.

The foregoing descriptions of the detailed embodiments are provided to illustrate and disclose the principles and functions of the present invention and are not intended to be restrictive of the scope of the present invention. It should be understood by those in the art that many modifications and variations can be made to the above embodiments without departing from the spirit and principles in the disclosure of the present invention such that those changes still fall within the scope of the invention as set forth in the appended claims.

What is claimed is:

1. An object-sensing device, comprising:
a carrier base having a carrying surface for carrying an object, the carrying surface being provided thereon with at least a first conductive element;
a cover capable of resting seamlessly on the carrying surface of the carrier base and provided therein with a receiving space open to the carrying surface;
a resilient element received in the receiving space of the cover;
at least a second conductive element disposed on a surface of the resilient element, wherein the surface of the resilient element faces the carrying surface, the at least a second conductive element corresponding in position to the first conductive element; and
a sensor electrically connected to the at least a first conductive element and an end of the at least a second conductive element and configured to detect electrical contact between each of the at least a first conductive element and another end of the at least a second conductive element to thereby determine whether an object is present on the carrying surface.

2. The object-sensing device of claim 1, wherein the sensor generates a first signal upon determination that each of the at least a first conductive element is in electrical contact with another end of the at least a second conductive element and generates a second signal upon determination that at least one of the at least a first conductive elements is not in electrical contact with another end of the at least a second conductive element.

3. The object-sensing device of claim 1, wherein the carrying surface and the resilient element are in seamless contact with each other.

4. The object-sensing device of claim 3, wherein the carrying surface and the resilient element are in seamless contact with each other through an arciform or curviform contact surface therebetween.

5. The object-sensing device of claim 1, wherein the cover is axially coupled to the carrier base.

6. The object-sensing device of claim 5, wherein the cover is provided with axles, and the carrier base is provided with axial holes corresponding in position to the axles, respectively.

7. The object-sensing device of claim 5, wherein the carrier base is provided with axles, and the cover is provided with axial holes corresponding in position to the axles, respectively.

8. The object-sensing device of claim 1, wherein the resilient element is at least one selected from the group consisting of a spring, a synthetic rubber piece, a foam rubber piece, and a sponge.

9. The object-sensing device of claim 1, wherein the at least a first conductive element and the at least a second conductive element are plate-like or columnar.

10. An object-sensing device, comprising:
a carrier base having a carrying surface for carrying an object, the carrying surface being provided thereon with at least a first conductive element;
a cover capable of resting seamlessly on the carrying surface of the carrier base and provided therein with a receiving space open to the carrying surface;
a resilient element received in the receiving space of the cover;
a baffle disposed on the resilient element;
at least a second conductive element disposed on a surface of the baffle, wherein the surface of the baffle faces the carrying surface, the at least a second conductive element corresponding in position to the at least a first conductive element; and
a sensor electrically connected to the at least a first conductive element and an end of the at least a second conductive element and configured to detect electrical contact between each of the at least a first conductive element and another end of the at least a second conductive element to thereby determine whether an object is present on the carrying surface.

11. The object-sensing device of claim 10, wherein the sensor generates a first signal upon determination that each of the at least a first conductive element is in electrical contact with another end of the at least a second conductive element and generates a second signal upon determination that at least one of the at least a first conductive element is not in electrical contact with another end of the at least a second conductive element.

12. The object-sensing device of claim 10, wherein the carrying surface and the baffle are in seamless contact with each other through an arciform or curviform contact surface therebetween, as are the baffle and the resilient element.

13. The object-sensing device of claim 10, wherein the cover is axially coupled to the carrier base.

14. The object-sensing device of claim 13, wherein the cover is provided with axles, and the carrier base is provided with axial holes corresponding in position to the axles, respectively.

15. The object-sensing device of claim 13, wherein the carrier base is provided with axles, and the cover is provided with axial holes corresponding in position to the axles, respectively.

16. The object-sensing device of claim 10, wherein the resilient element is at least one selected from the group consisting of a spring, a synthetic rubber piece, a foam rubber piece, and a sponge.

17. The object-sensing device of claim 10, wherein the first conductive element and the at least a second conductive element are plate-like or columnar.

18. An object-sensing device, comprising:
a carrier base having a carrying surface for carrying an object, the carrying surface being provided thereon with at least a first conductive element;
a cover capable of resting seamlessly on the carrying surface of the carrier base and provided therein with a receiving space open to the carrying surface;
a resilient element received in the receiving space of the cover;
at least a second conductive element disposed on a surface of the resilient element, wherein the surface of the resilient element faces the at least a first conductive element, the at least a second conductive element being provided with conductive bumps corresponding in position to the at least a the first conductive element;
a baffle disposed on the at least a second conductive element and provided with openings corresponding in position to the conductive bumps, respectively; and
a sensor electrically connected to the at least a first conductive element and an end of the at least a second conductive element and configured to detect electrical contact between each of the at least a first conductive element and another end of the at least a second conductive element to thereby determine whether an object is present on the carrying surface.

19. The object-sensing device of claim 18, wherein the sensor generates a first signal upon determination that each of the at least a first conductive elements is in electrical contact with another end of the at least a second conductive element and generates a second signal upon determination that at least one of the at least a first conductive elements is not in electrical contact with another end of the at least a second conductive element.

20. The object-sensing device of claim 18, wherein the carrying surface and the baffle are in seamless contact with each other through an arciform or curviform contact surface therebetween, as are the baffle and the resilient element.

21. The object-sensing device of claim 18, wherein the cover is axially coupled to the carrier base.

22. The object-sensing device of claim 21, wherein the cover is provided with axles, and the carrier base is provided with axial holes corresponding in position to the axles, respectively.

23. The object-sensing device of claim 21, wherein the carrier base is provided with axles, and the cover is provided with axial holes corresponding in position to the axles, respectively.

24. The object-sensing device of claim 18, wherein the resilient element is at least one selected from the group consisting of a spring, a synthetic rubber piece, a foam rubber piece, and a sponge.

25. The object-sensing device of claim 18, wherein the first conductive element and the at least a second conductive element are plate-like or columnar.
